(19) United States
(12) Patent Application Publication
(10) Pub. No.: US 2013/0154452 A1
(43) Pub. Date: Jun. 20, 2013

(54) ELECTRONIC DEVICE ENCLOSURE

(71) Applicants: YUN-LUNG CHEN, Tu-Cheng (TW); LIANG-CHIN WANG, Tu-Cheng (TW); YU-MING XIAO, Wuhan City (CN); HAI-QING ZHU, Wuhan City (CN); XIAO-FEI ZHOU, Wuhan City (CN)

(72) Inventors: YUN-LUNG CHEN, Tu-Cheng (TW); LIANG-CHIN WANG, Tu-Cheng (TW); YU-MING XIAO, Wuhan City (CN); HAI-QING ZHU, Wuhan City (CN); XIAO-FEI ZHOU, Wuhan City (CN)

(73) Assignees: HON HAI PRECISION INDUSTRY CO., LTD., Tu-Cheng (TW); HONG FU JIN PRECISION INDUSTRY (WUHAN) CO., LTD., Wuhan City (CN)

(21) Appl. No.: 13/596,709

(22) Filed: Aug. 28, 2012

(30) Foreign Application Priority Data
Dec. 20, 2011 (CN) 201110429613.3

(51) Int. Cl. H05K 7/14

(52) U.S. Cl. 312/223.1

(57) ABSTRACT

An electronic device enclosure includes a mounting device and a chassis. The mounting device, for securing a connector, includes a limiting protrusion, an installation protrusion, two resilient pieces, and two mounting protrusions extending from the two resilient pieces. The chassis includes a front plate defining an installation opening. The front plate includes two mounting pieces, and each of the two mounting pieces defines a mounting hole. The mounting device is secured between the two mounting pieces. The installation protrusion abuts an inner surface of the front plate through the installation opening. The limiting protrusion abuts an outer surface of the front plate. Each mounting protrusion is engaged in the mounting hole of each mounting piece.

### BACKGROUND

1. Technical Field

The present disclosure relates to electronic device enclosures, and particularly to an electronic device enclosure to which a connector is secured.

2. Description of Related Art

A number of connectors, such as Universal Serial Bus (USB) jacks and audio jacks, are secured to a front plate of a chassis of an electronic device, such as a computer. Generally, the connectors are mounted in an enclosure, and the enclosure is secured to the front plate with screws, which is laborious and time consuming. Therefore, there is room for improvement in the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an exploded, isometric view of one embodiment of an electronic device enclosure.

FIG. 2 shows the one embodiment of an electronic device enclosure of FIG. 1, but viewed from a different aspect.

FIG. 3 is an isometric view of a securing member of the electronic device enclosure of FIG. 1.

FIG. 4 is an assembled, isometric view of the electronic device enclosure of FIG. 1.

FIG. 5 shows the one embodiment of an electronic device enclosure of FIG. 4, but viewed from a different aspect.

FIG. 6 is a cross-sectional view of the electronic device enclosure of FIG. 4 taken along a line VI-VI.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean “at least one.”

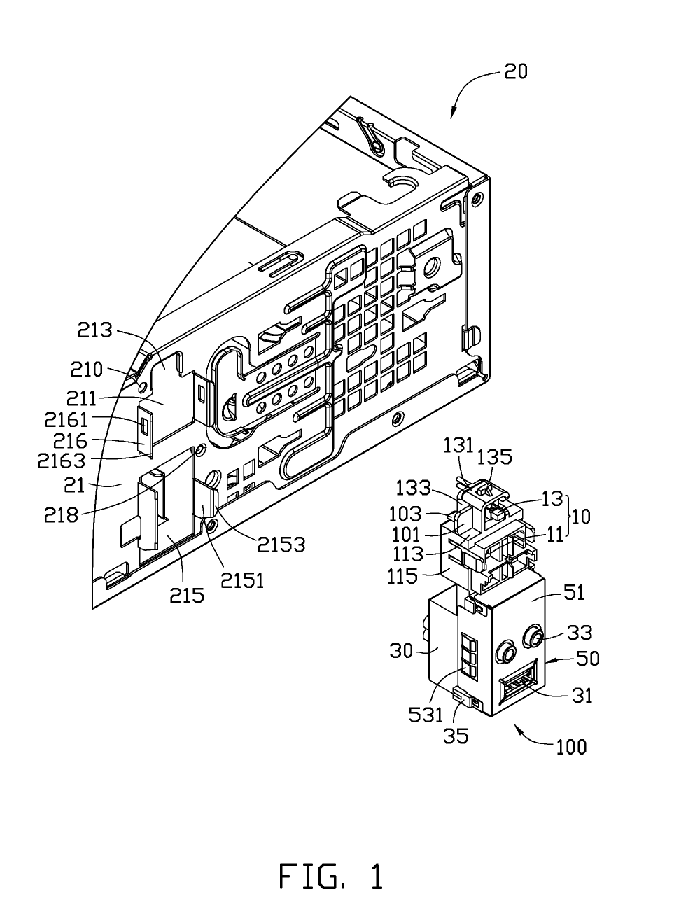

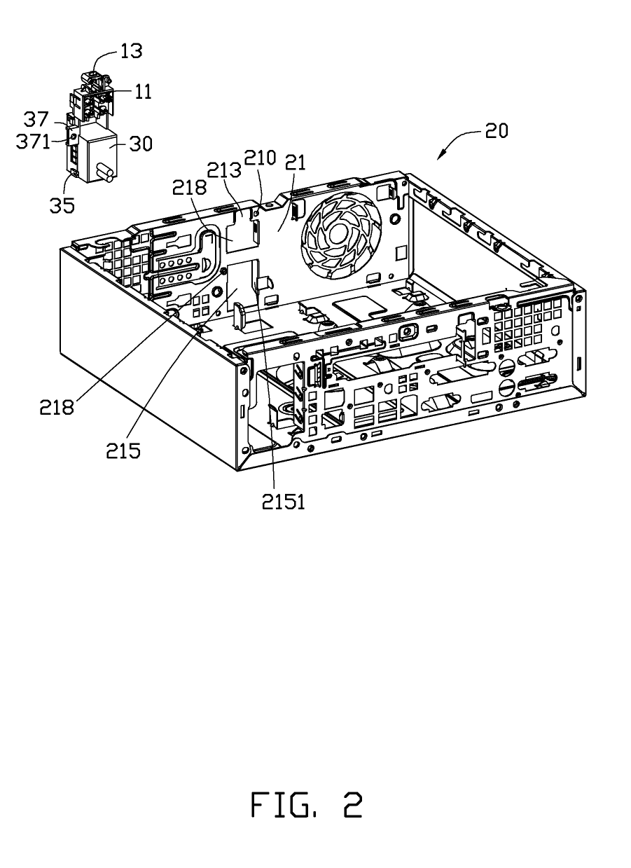

Referring to FIG. 1 and FIG. 2, an electronic device enclosure in accordance with an embodiment is shown. The electronic device enclosure comprises a mounting device 100 and a chassis 20. The chassis 20 comprises a front plate 21. The mounting device 100 can be secured to the front plate 21.

The front plate 21 defines a mounting opening 211, a through opening 213, and an installation opening 215. The mounting opening 211 communicates with the through opening 213. The mounting opening 211 is located between the through opening 213 and the installation opening 215. A mounting piece 216 extends from each of two opposite edges of the mounting opening 211. In one embodiment, the mounting piece 216 is substantially perpendicular to the front plate 21. The mounting piece 216 defines a mounting hole 2161. A mounting flange 2163 extends from an edge of the mounting piece 216. An obtuse angle is defined between the mounting flange 2163 and the mounting piece 216. The front plate 21 defines a limiting hole 210 and a first locking hole 218. The limiting hole 210 is adjacent to the mounting opening 211 and the through opening 213. The first locking hole 218 is adjacent to the installation opening 215. An installation piece 2151 extends from each of two opposite edges of the installation opening 215. In one embodiment, the installation piece 2151 is substantially perpendicular to the front plate 21. An installation flange 2153 extends from an edge of the installation piece 2151. An obtuse angle is defined between the installation flange 2153 and the installation piece 2151.

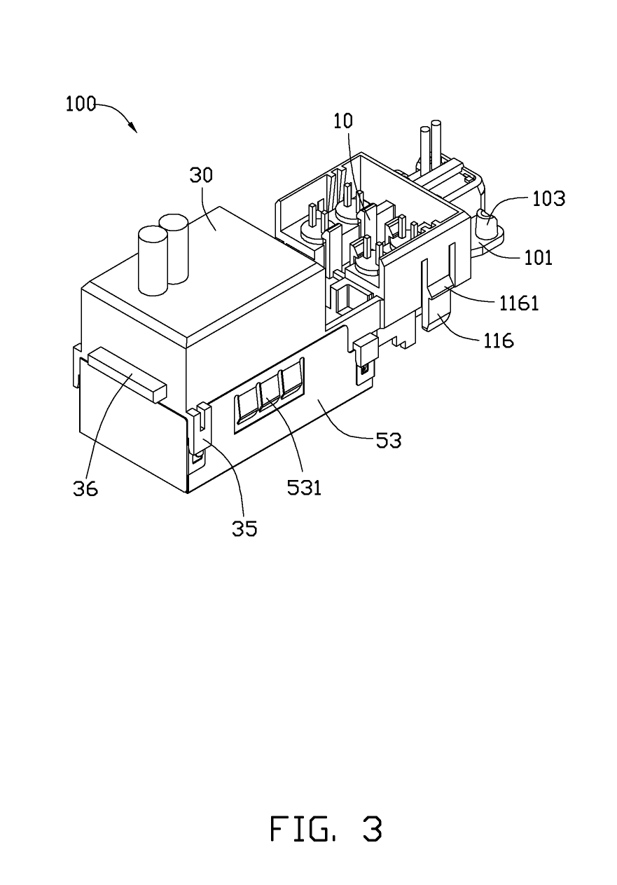

FIGS. 1-3 show the mounting device 100 including a mounting assembly 10 and a connecting assembly 30 connected to the mounting assembly 10.

The mounting assembly 10 comprises a mounting portion 11 and a limiting portion 13. The mounting portion 11 comprises a top wall 113 and two sidewalls 115. In one embodiment, the two sidewalls 115 are substantially parallel to each other, and the two sidewalls 115 are substantially perpendicular to the top wall 113. A resilient piece 116 extends from each sidewall 115. A mounting protrusion 1161 protrudes from the resilient piece 116. The mounting protrusion 1161 can be engaged in the mounting hole 2161. The limiting portion 13 is located on the top wall 113 and comprises a top plate 131 and two side plates 133. In one embodiment, the top plate 131 is substantially parallel to the top wall 113, and the side plate 133 is substantially parallel to the sidewall 115. A limiting protrusion 135 protrudes from the top plate 131. A limiting piece 101 extends from side plate 133 and the top wall 113, and is located in a corner between the side plate 133 and the top wall 113. In one embodiment, the limiting piece 101 is substantially perpendicular to the side plate 133 and the top wall 113. A limiting post 103 extends from the limiting piece 101 and can be inserted into the limiting hole 210.

A first connector 31 and two second connectors 33 are secured to the connecting assembly 30. In one embodiment, the first connector 31 is a USB jack. The two second connectors 33 are two audio jacks. A latching block 35 extends from each of two opposite side surfaces of the connecting assembly 30. A locking piece 37 extends from one of the two side surfaces of the connecting assembly 30. A gap (not shown) is defined between each latching block 35 and the side surface of the connecting assembly 30. The locking piece 37 defines a second locking hole 371. A shielding 50 surrounds the connecting assembly 30. The shielding 50 comprises a front board 51 and two side boards 53. The first connector 31 and the two second connectors 33 extend out of the front board 51. Each side board 53 engages in the gap between each latching block 35 and the side surface of the connecting assembly 30. Each side board 53 comprises a plurality of pressing pieces 531. An installation protrusion 36 extends from a bottom end of the connecting assembly 30.

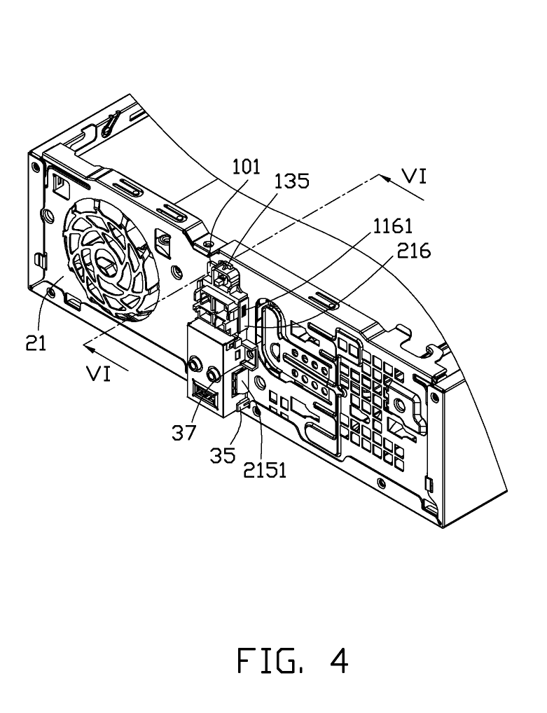

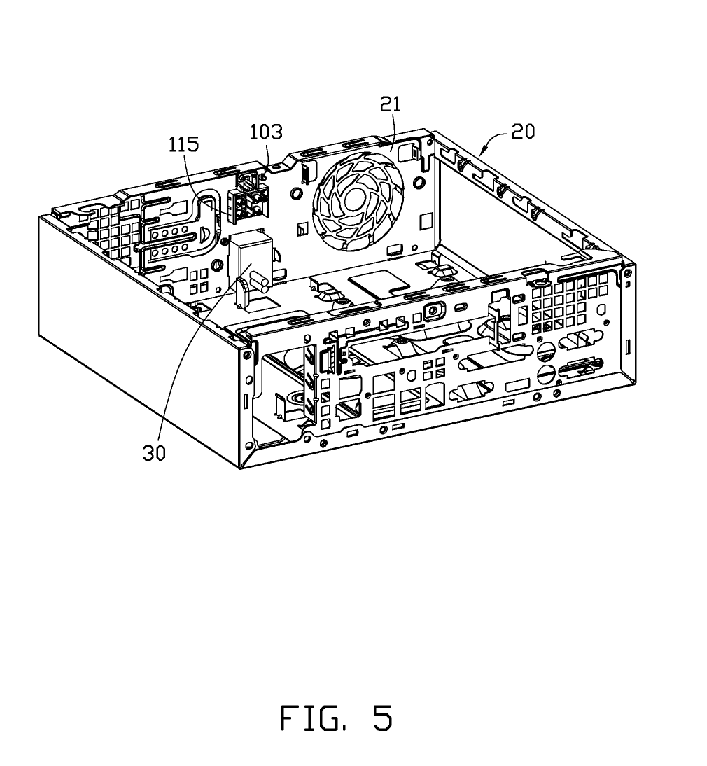

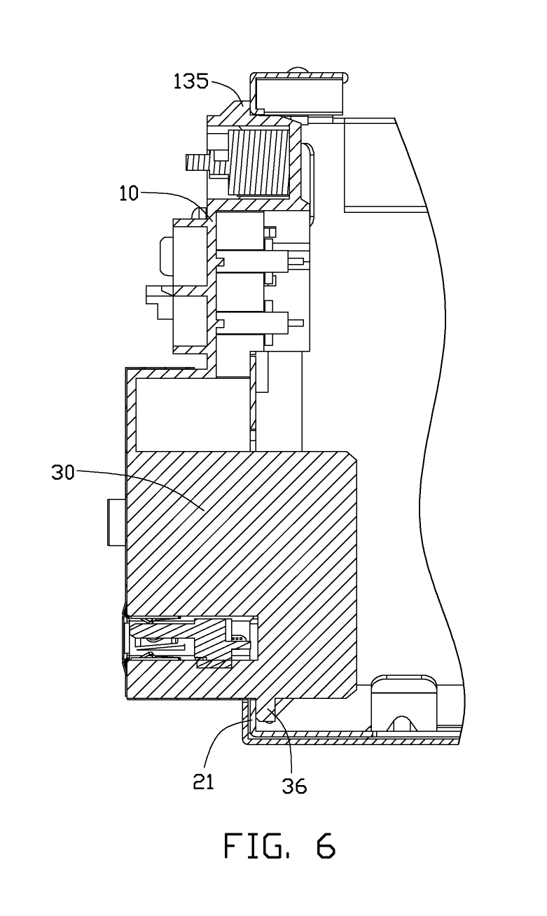

FIGS. 4-6 show assembly of the electronic device enclosure of an embodiment. The mounting assembly 10 is moved to be adjacent to the front plate 21. The mounting portion 11 is aligned with the mounting opening 211. The limiting portion is aligned with the through opening 213. The connecting assembly 30 is aligned with the installation opening 215. The mounting assembly 10 is bent to insert the installation protrusion 36 into the front plate 21 through the installation opening 215, and the installation protrusion 36 abuts an inner surface of the front plate 21. The mounting device 100 is rotated towards the front plate 21, the connecting assembly 30 is located between the two installation pieces 2151, and the mounting assembly 10 is received between the two mounting pieces 216. The two installation pieces 2151 press against and elastically deform the pressing piece 531. The two mounting pieces 216 press against and elastically deform the resilient piece 116. The mounting device 100 is further moved until the limiting protrusion 135, the limiting piece 101, the locking piece 37, and the latching block 35 abut an outer surface of the front plate 21. The limiting post 103 is inserted into the limiting hole 210. The resilient piece 116 restores to engage the mounting protrusion 1161 in the mounting hole 2161. The pressing piece 531 exerts elastic force to abut the two installation pieces 2151. The second locking hole 371 is aligned with the first locking hole 218. In one embodiment, a locking member, such as a screw, is locked into the second locking hole 371 and the first locking hole 218, so that the mounting device 100 is further secured to the front plate 21.

In disassembly, the two resilient pieces 116 are elastically deformed towards each other to disengage the limiting protrusion 135 from the mounting hole 2161. The mounting device 100 is rotated away from the front plate 21. The pressing piece 531 is disengaged from the two installation pieces 2151. The mounting device 100 is moved upwards, the installation protrusion 36 is disengaged from the inner surface of the front plate 21. In this way, the mounting device 100 is removed from the front plate 21.

It is to be understood, however, that even though numerous characteristics and advantages have been set forth in the foregoing description of embodiments, together with details of the structures and functions of the embodiments, the disclosure is illustrative only and changes may be made in detail, especially in the matters of shape, size, and the arrangement of parts within the principles of the disclosure, to the full extent indicated by the broad general meaning of the terms in which the appended claims are expressed.

What is claimed is:

1. An electronic device enclosure, comprising:
a mounting device, for securing a connector, comprising a limiting protrusion, an installation protrusion, two resilient pieces, and two mounting protrusions extending from the two resilient pieces; and
a chassis comprising a front plate defining an installation opening, the front plate comprising two mounting pieces, and each of the two mounting pieces defines a mounting hole;
wherein the mounting device is secured between the two mounting pieces; the installation protrusion abuts an inner surface of the front plate through the installation opening; the limiting protrusion abuts an outer surface of the front plate; and each mounting protrusion is engaged in the mounting hole of each mounting piece.

2. The electronic device enclosure of claim 1, wherein the two mounting pieces are substantially perpendicular to the front plate.

3. The electronic device enclosure of claim 1, wherein the mounting device further comprises a mounting assembly and a connecting assembly connected to the mounting assembly; the mounting assembly comprises a mounting portion and a limiting portion, and the mounting portion is located between the limiting portion and the connecting assembly; and the installation protrusion extends from a bottom end of the connecting assembly, and the limiting protrusion extends from a top end of the limiting portion.

4. The electronic device enclosure of claim 3, wherein the mounting portion comprises a top wall and two sidewalls substantially perpendicularly connected to the top wall; the limiting portion extends from the top wall, and each of the two resilient pieces extends from each of the two sidewalls.

5. The electronic device enclosure of claim 4, wherein the limiting portion comprises a top plate, the top plate is substantially parallel to the top wall, and the limiting protrusion protrudes from the top plate.

6. The electronic device enclosure of claim 5, wherein the mounting assembly further comprises a limiting piece located in a corner between the mounting portion and the limiting portion; and the limiting piece abuts the outer surface of the front plate, and the limiting piece is substantially perpendicular to the top plate and the top wall.

7. The electronic device enclosure of claim 6, wherein the mounting assembly further comprises a limiting post extending from the limiting piece, the front plate defines a limiting hole, and the limiting post is engaged in the limiting hole.

8. The electronic device enclosure of claim 4, wherein the connecting assembly further comprises a shielding; the shielding comprises two side boards, and the two side boards are substantially parallel to the two sidewalls; the front plate further comprises two installation pieces extending from opposite two side edges of the installation opening; and the connecting assembly is located between the two installation pieces.

9. The electronic device enclosure of claim 8, wherein each of the two side boards comprises a pressing piece, and the pressing piece is elastically deformable to abut one of the two installation pieces.

10. The electronic device enclosure of claim 8, wherein the mounting device further comprises two latching blocks extending from two opposite surfaces of the connecting assembly; the two latching blocks abut the outer surface of the front plate; and each of the two side boards is secured between each of the two latching blocks and each of the two opposite surfaces of the connecting assembly.

11. An electronic device enclosure, comprising:
a mounting device, for securing a connector, comprising a mounting assembly, a connecting assembly connected to the mounting assembly, and a shielding surrounding the connecting assembly; the mounting assembly comprising a limiting protrusion, two resilient pieces, and two mounting protrusions extending from the two resilient pieces; the connecting assembly comprising an installation protrusion; and the shielding comprising two pressing pieces; and
a chassis comprising a front plate defining an installation opening, the front plate comprising two mounting pieces and two installation pieces, and each of the two mounting pieces defines a mounting hole;
wherein the mounting assembly is secured between the two mounting pieces, and each mounting protrusion is engaged in the mounting hole of each mounting piece; the connecting assembly and the shielding is secured between the two installation pieces, and the two pressing pieces abuts the two installation pieces; the installation protrusion abuts an inner surface of the front plate through the installation opening; and the limiting protrusion abuts an outer surface of the front plate.

12. The electronic device enclosure of claim 11, wherein the two mounting pieces are substantially perpendicular to the front plate.

13. The electronic device enclosure of claim 11, wherein the mounting assembly further comprises a mounting portion and a limiting portion, and the mounting portion is located between the limiting portion and the connecting assembly; and the installation protrusion extends from a bottom end of the connecting assembly, and the limiting protrusion extends from a top end of the limiting portion.

14. The electronic device enclosure of claim 13, wherein the mounting portion comprises a top wall and two sidewalls substantially perpendicularly connected to the top wall; the limiting portion extends from the top wall, and each of the two resilient pieces extends from each of the two sidewalls.

15. The electronic device enclosure of claim 14, wherein the limiting portion comprises a top plate, the top plate is substantially parallel to the top wall, and the limiting protrusion protrudes from the top plate.

16. The electronic device enclosure of claim 15, wherein the mounting assembly further comprises a limiting piece located in a corner between the mounting portion and the limiting portion; and the limiting piece abuts the outer surface of the front plate, and the limiting piece is substantially perpendicular to the top plate and the top wall.

17. The electronic device enclosure of claim 16, wherein the mounting assembly further comprises a limiting post extending from the limiting piece, the front plate defines a limiting hole, and the limiting post is engaged in the limiting hole.

18. The electronic device enclosure of claim 14, wherein the shielding further comprises two side boards, and the two side boards are substantially parallel to the two sidewalls; and
the two installation pieces extending from opposite two side edges of the installation opening.

19. The electronic device enclosure of claim 18, wherein each of the two pressing pieces extends from each of the two side boards, and each of the two pressing pieces extends is elastically deformable to abut each of the two installation pieces.

20. The electronic device enclosure of claim 18, wherein the mounting device further comprises two latching blocks extending from two opposite surfaces of the connecting assembly; the two latching blocks abut the outer surface of the front plate; and each of the two side boards is secured between each of the two latching blocks and each of the two opposite surfaces of the connecting assembly.
